(19) United States
(12) Patent Application Publication
(10) Pub. No.: US 2018/0248095 A1
(43) Pub. Date: Aug. 30, 2018

(54) Bonding Structure for III-V Group Compound Device

(71) Applicant: XIAMEN SANAN OPTOELECTRONICS TECHNOLOGY CO., LTD., Xiamen (CN)

(72) Inventors: Cheng MENG, Xiamen (CN); Chun-Yi WU, Xiamen (CN); Ching-Shan TAO, Xiamen (CN); Duxiang WANG, Xiamen (CN)

(73) Assignee: XIAMEN SANAN OPTOELECTRONICS TECHNOLOGY CO., LTD., Xiamen (CN)

(21) Appl. No.: 15/967,604

(22) Filed: May 1, 2018

Related U.S. Application Data
(63) Continuation of application No. PCT/CN2016/097804, filed on Sep. 1, 2016.

(30) Foreign Application Priority Data
Nov. 6, 2015 (CN) 201510744855.X

(51) Int. Cl. H01L 33/64; H01L 33/30

(52) U.S. Cl. CPC H01L 33/641; H01L 33/30

(57) ABSTRACT

A bonding structure for III-V group compound devices includes a first metal bonding layer and a second metal bonding layer. The second metal bonding layer is internally embedded with a nano-conductive film, and the nano-conductive film, with thermal conductivity higher than that of the second metal bonding layer, is completely wrapped by the second metal bonding layer for low temperature bonding and fast heat dissipation. Such a bonding structure can be employed by a light-emitting diode.

### CROSS-REFERENCE TO RELATED APPLICATIONS

The present application is a continuation of, and claims priority to, PCT/CN2016/097804 filed on Sep. 1, 2016, which claims priority to Chinese Patent Application No. 201510744855.X filed on Nov. 6, 2015. The disclosures of these applications are hereby incorporated by reference in their entirety.

### BACKGROUND

With the development of semiconductor photoelectric devices made of III-V group compounds, heat dissipation characteristic has become one of the major elements that affect device characteristics. In a light-emitting diode (LED), when external current is put into the red-light LED, some electric energy will be changed to heat energy. Chip temperature will rise to above 85° C. from original room temperature, and attenuation rate from luminance on temperature is about −0.87%/° C. Meanwhile, light-emitting wavelength will drift towards long wavelength as temperature rises (taking red-light LED as an example, when red-light band wavelength increases by every 1 nm, luminance attenuates about 4%). Therefore, if heat energy generated by the chip dissipates timely, the chip will be kept at room temperature without wavelength drift and luminance attenuation.

### SUMMARY

The present disclosure relates to a bonding structure with fast heat dissipation for III-V group compound devices, and a light-emitting diode with such bonding structure.

The inventors of the present disclosure have recognized that, among growth substrates of existing light-emitting diodes, growth substrates of GaN-based light-emitting diodes are mainly of sapphire substrates, and growth substrates of AlGaInP-based light-emitting diodes are mainly of GaAs growth substrates. However, both sapphire and GaAs feature poor thermal and electrical conductivity. A prior art discloses a flip-chip structure (as shown in FIG. 1). In this type of LED structure, the epitaxy wafer is bonded with the conductive substrate by a metal bonding layer. In the above flip-chip structure, in general, an Au—Au structure is adopted as high bonding temperature will damage Al or Ag mirror structure, thus affecting mirror reflectivity. To solve this problem, Chinese patent CN 101604714A discloses the adoption of Au—In low temperature bonding. However, low thermal conductivity (82-86 W/mk) of In is unfavorable for fast heat dissipation of device from the bonding structure.

To solve the above problems, embodiments of the present disclosure provide a bonding structure with low temperature bonding and fast heat dissipation for III-V group compound devices. A technical approach according to some embodiments of the present disclosure to solve the above problems includes: a bonding structure for III-V group compound devices includes a first metal bonding layer and a second metal bonding layer. The second metal bonding layer is internally embedded with a nano-conductive film, and the nano-conductive film, with thermal conductivity higher than that of the second metal bonding layer, is completely wrapped by the second metal bonding layer; the second metal bonding layer material is of sufficiently low hardness for complete dipping of the nano-conductive film, thus interface contact resistance is reduced.

In some embodiments, melting point of the second metal bonding layer is lower than 350° C.

In some embodiments, the second metal bonding layer is an In bonding layer, a Sn bonding layer or a Pb bonding layer.

In some embodiments, the first metal bonding layer is an Au bonding layer, and the second metal bonding layer is an In bonding layer.

In some embodiments, the nano-conductive film is a carbon nanotube layer or a graphene film layer.

In some embodiments, the nano-conductive film is a single carbon nanotube layer or is laminated by multiple carbon nanotube layers.

In some embodiments, the nano-conductive film is a single graphene film layer or is laminated by multiple graphene film layers.

In some embodiments, the nano-conductive film is alternatively laminated by carbon nanotube layers and graphene film layers, wherein the top layer and the bottom layer are graphene film layers.

In a second aspect, the present disclosure also provides a light-emitting diode with the above bonding structure including a light-emitting epitaxial laminated layer and a conductive substrate, wherein, the light-emitting epitaxial laminated layer is bonded with the conductive substrate by a bonding structure. The nanometer film layer embedded in the second metal bonding layer, with thermal conductivity far higher than that of the second metal bonding layer, is completely embedded in the film having no direct contact with the substrate or the epitaxial laminated layer.

In a third aspect, the present disclosure also provides a light-emitting system, including a plurality of light-emitting diodes. The light-emitting system can be used in lighting, display, signage, etc. Each of the light-emitting diodes with the above bonding structure including a light-emitting epitaxial laminated layer and a conductive substrate, wherein, the light-emitting epitaxial laminated layer is bonded with the conductive substrate by a bonding structure. The nanometer film layer embedded in the second metal bonding layer, with thermal conductivity far higher than that of the second metal bonding layer, is completely embedded in the film having no direct contact with the substrate or the epitaxial laminated layer.

The other features and advantages of this present disclosure will be described in detail in the following specification, and it is believed that such features and advantages will become more obvious in the specification or through implementations of this disclosure. The purposes and other advantages of the present disclosure can be realized and obtained in the structures specifically described in the specifications, claims and drawings.

### BRIEF DESCRIPTION OF THE DRAWINGS

The accompanying drawings, which are included to provide a further understanding of the disclosure and constitute a part of this specification, together with the embodiments, are therefore to be considered in all respects as illustrative and not restrictive. In addition, the drawings are merely illustrative, which are not drawn to scale.

FIG. 1 illustrate a sectional view of an existing flip-chip light-emitting diode structure.

FIG. 2 illustrate a sectional view of a light-emitting diode structure according to Embodiment 1 of the present disclosure.

FIG. 3 illustrate a sectional view of a bonding structure for III-V group compound devices according to Embodiment 2 of the present disclosure.

FIG. 4 illustrate a sectional view of a bonding structure for III-V group compound device according to Embodiment 3 of the present disclosure.

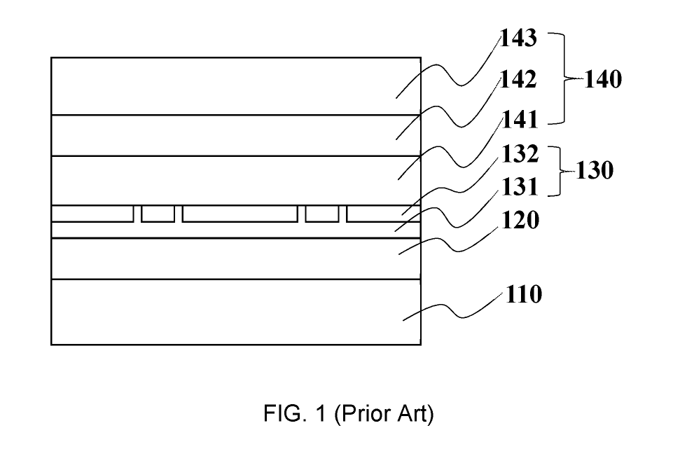

In the drawing: 110, 210: conductive substrate; 120, 220: bonding structure; 130: omni-directional reflector (ODR); 131, 231: metal reflective layer; 132, 232: dielectric layer; 141, 241: first semiconductor layer; 142, 242: active layer; 143, 243: second semiconductor layer; 221: first metal bonding layer; 222: second metal bonding layer; 2221: carbon nanotube layer; 2222: graphene film layer.

### DETAILED DESCRIPTION

The bonding structure of the present disclosure will be described in detail with reference to the accompanying drawings, to help understand and practice the disclosed embodiments, regarding how to solve technical problems using technical approaches for achieving the technical effects. It should be understood that the embodiments and their characteristics described in this disclosure may be combined with each other and such technical proposals are deemed to be within the scope of this disclosure without departing from the spirit of this disclosure.

The embodiments below disclose a bonding structure with fast heat dissipation for III-V group compound devices, and a light-emitting diode with such bonding structure. The bonding layer is made of low melting point material and the bonding layer with low melting point is internally embedded with a nano-conductive film with thermal conductivity far higher than that of the bonding layer for low temperature bonding and fast heat dissipation. The bonding layer material is of low hardness (such as In, Sn or Pb) to make it easy for complete dipping of the nano-conductive film, thus reducing interface contact resistance.

### Embodiment 1

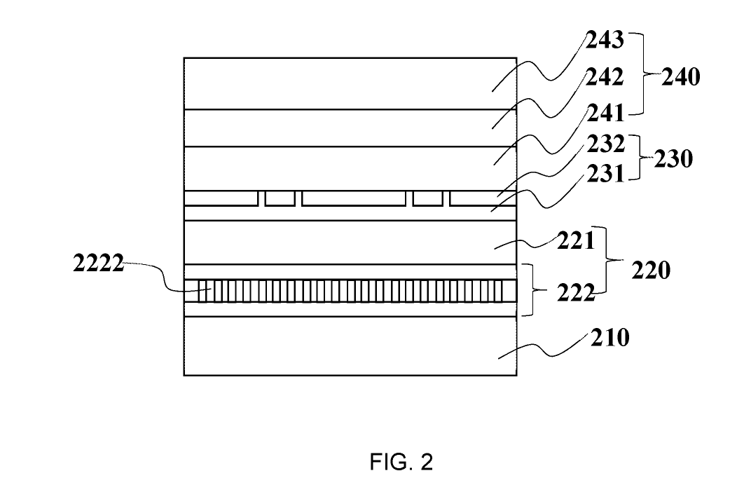

With reference to FIG. 2, a light-emitting diode includes a conductive substrate 210, a bonding structure 220, an omni-directional reflector 230 and a light-emitting epitaxial laminated layer 240. The conductive substrate 210 is made of high-thermal conductivity material, generally a Si substrate. The bonding structure 220 is composed of a first metal bonding layer 221 and a second metal bonding layer 222. The omni-directional reflector 230 is composed of a metal reflective layer 231 and a dielectric layer 232 with low refractive index. The light-emitting epitaxial laminated layer 240 generally includes a first semiconductor layer 241, an active layer 242 and a second semiconductor layer 243, but is not limited to the above layers. Details will be given below for the bonding structure 220.

Specifically, the bonding structure 220 is an Au—In structure, wherein, the first metal bonding layer 221 is an Au bonding layer, and the second metal bonding layer 222 is an In bonding layer. The In bonding layer is embedded with a nano film layer with high thermal conductivity, which is as high as possible and must be higher than that of In material. In this embodiment, the thermal conductive film is a carbon nanotube layer, which is a single layer structure that is completely wrapped in the In bonding layer.

In the above bonding structure, In melting point is low and is suitable for low temperature bonding. Meanwhile, the graphene film layer, with thermal conductivity far higher than that of In (thermal conductivity of In is 82-86, and thermal conductivity of graphene is 4,400-5,780), is wrapped in the In bonding layer. In is extremely soft (with hardness degree of 1.2), which makes it easy for complete dipping of the graphene film layer, thus reducing interface contact resistance and achieving fast thermal conduction.

### Embodiment 2

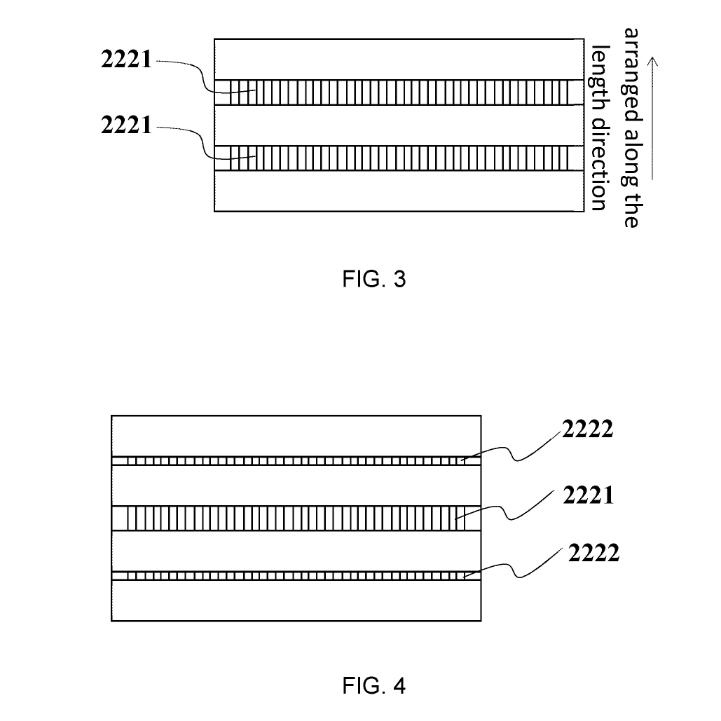

With reference to FIG. 3, in this embodiment, the nano-conductive film has multiple carbon nanotube layers 2221 arranged along the length directions, which show good heat exchange performance due to heat dissipation anisotropy of carbon nanotubes.

### Embodiment 3

With reference to FIG. 4, in this embodiment, the nano-conductive film is alternatively laminated by carbon nanotube layers 2221 and graphene film layers 2222, wherein, the top layer and bottom layer are graphene film layers. With this structure, heat approaching the light-emitting epitaxial laminated layer can be exported from epitaxy in a fastest speed, and bottom heat can be quickly exported from the chip through the film layer with high thermal conductivity near the outer side.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A bonding structure for a III-V group compound device, comprising:
a first metal bonding layer; and
a second metal bonding layer;
wherein the second metal bonding layer is internally embedded with a nano-conductive film with thermal conductivity higher than that of the second metal bonding layer;
the nano-conductive film is completely wrapped by the second metal bonding layer; and
the second metal bonding layer material is of sufficiently low hardness for complete dipping of the nano-conductive film, thus reducing interface contact resistance.

2. The bonding structure for the III-V group compound device of claim 1, wherein a melting point of the second metal bonding layer is lower than 350° C.

3. The bonding structure for the III-V group compound device of claim 2, wherein the second metal bonding layer is an In bonding layer, a Sn bonding layer or a Pb bonding layer.

4. The bonding structure for the III-V group compound device of claim 1, wherein the first metal bonding layer is an Au bonding layer, and the second metal bonding layer is an In bonding layer.

5. The bonding structure for the III-V group compound device of claim 1, wherein the nano-conductive film is a carbon nanotube layer or a graphene film layer.

6. The bonding structure for the III-V group compound device of claim 1, wherein the nano-conductive film is a single carbon nanotube layer or is laminated by multiple carbon nanotube layers.

7. The bonding structure for the III-V group compound device of claim 6, wherein the nanotube layers are arranged along a length direction.

8. The bonding structure for the III-V group compound device of claim 1, wherein the nano-conductive film is a single graphene film layer or is laminated by multiple graphene film layers.

9. The bonding structure for the III-V group compound device of claim 1, wherein the nano-conductive film is alternatively laminated by carbon nanotube layers and graphene film layers, wherein, the top layer and bottom layer are graphene film layers.

10. A light-emitting diode, comprising:
a light-emitting epitaxial laminated layer;
a bonding structure; and
a conductive substrate;
wherein the light-emitting epitaxial laminated layer is bonded with the conductive substrate by the bonding structure;
the bonding structure comprises:
a first metal bonding layer; and
a second metal bonding layer;
wherein the second metal bonding layer is internally embedded with a nano-conductive film with thermal conductivity higher than that of the second metal bonding layer;
the nano-conductive film is completely wrapped by the second metal bonding layer; and
the second metal bonding layer material is of sufficiently low hardness for complete dipping of the nano-conductive film, thus reducing interface contact resistance.

11. The light-emitting diode of claim 10, wherein the first metal bonding layer is an Au bonding layer, and the second metal bonding layer is an In bonding layer.

12. The light-emitting diode of claim 10, wherein the nano-conductive film is alternatively laminated by carbon nanotube layers and graphene film layers, wherein, the graphene film layer is close to the light-emitting epitaxial laminated layer and the conductive substrate.

13. The light-emitting diode of claim 10, wherein a melting point of the second metal bonding layer is lower than 350° C.

14. The light-emitting diode of claim 13, wherein the second metal bonding layer is an In bonding layer, a Sn bonding layer or a Pb bonding layer.

15. The light-emitting diode of claim 10, wherein the nano-conductive film is a carbon nanotube layer or a graphene film layer.

16. The light-emitting diode of claim 10, wherein the nano-conductive film is a single carbon nanotube layer or is laminated by multiple carbon nanotube layers.

17. The light-emitting diode of claim 16, wherein the nanotube layers are arranged along a length direction.

18. The light-emitting diode of claim 10, wherein the nano-conductive film is a single graphene film layer or is laminated by multiple graphene film layers.

19. A light-emitting system comprising a plurality of light-emitting diodes, wherein each of the plurality of light-emitting diodes comprises:
a light-emitting epitaxial laminated layer;
a bonding structure; and
a conductive substrate;
wherein the light-emitting epitaxial laminated layer is bonded with the conductive substrate by the bonding structure;
the bonding structure comprises:
a first metal bonding layer; and
a second metal bonding layer;
wherein the second metal bonding layer is internally embedded with a nano-conductive film with thermal conductivity higher than that of the second metal bonding layer;
the nano-conductive film is completely wrapped by the second metal bonding layer; and
the second metal bonding layer material is of sufficiently low hardness for complete dipping of the nano-conductive film, thus reducing interface contact resistance.

20. The light-emitting system of claim 19, wherein the first metal bonding layer is an Au bonding layer, and the second metal bonding layer is an In bonding layer.
